(19) United States
(12) Patent Application Publication
(10) Pub. No.: US 2016/0042945 A1
(43) Pub. Date: Feb. 11, 2016

(54) COVERAGE OF HIGH ASPECT RATIO FEATURES USING SPIN-ON DIELECTRIC THROUGH A WETTED SURFACE WITHOUT A PRIOR DRYING STEP

(71) Applicant: Lam Research Corporation, Fremont, CA (US)

(72) Inventors: Ratchana Limary, Austin, TX (US); Nerissa Draeger, Fremont, CA (US); Diane Hymes, San Jose, CA (US); Richard Gottscho, Pleasanton, CA (US)

(21) Appl. No.: 14/456,235

(22) Filed: Aug. 11, 2014

(51) Int. Cl. H01L 21/02

(52) U.S. Cl. CPC H01L 21/02301; H01L 21/02282; H01L 21/0231

(57) ABSTRACT

A method includes depositing a film solution onto a patterned feature of a semiconductor substrate after wet cleaning the semiconductor substrate and without performing a drying step after the wet cleaning. The film solution includes a dielectric film precursor or a dielectric film precursor and at least one of a reactant, a solvent, a surfactant and a carrier fluid. The method includes baking at least one of solvent and unreacted solution out of a film formed by the film solution by heating the substrate to a baking temperature. The method includes curing the substrate.

### FIELD

The present disclosure relates to substrate processing methods and more particularly to methods for depositing film on a substrate.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Fabrication of substrates such as semiconductor wafers typically requires multiple processing steps that may include material deposition, planarization, feature patterning, feature etching, and feature cleaning. These processing steps are typically repeated one or more times during processing of the substrate.

As semiconductor devices continue to scale down to smaller feature sizes, high aspect ratio (HAR) structures are increasingly required to achieve desired device performance objectives. The use of the HAR structures creates challenges for some of the substrate processing steps. For example, wet processes such as etch and clean pose problems for the HAR structures due to capillary forces that are generated during drying of the substrate. The strength of the capillary forces depends upon surface tension, a contact angle of the etch, clean, or rinse fluids that are being dried, feature spacing and/or an aspect ratio of the features. If the capillary forces generated during drying are too high, the HAR features will become strained or collapse onto each other and stiction may occur, which severely degrades device yield.

To solve this problem, one approach uses rinsing liquids that have a lower surface tension than deionized water to prevent the features from collapsing. While generally successful for relatively low aspect ratio structures, this approach has the same collapse and stiction issues as methods that use deionized water. The rinse fluids still possess a finite amount of surface tension that generates forces during drying that are still too strong for the fragile HAR structures.

An alternative approach for drying HAR structures involves dissolving and flushing the rinsing fluid with a supercritical fluid. Supercritical fluids are free of surface tension when processed correctly. However, several technical and manufacturing challenges arise when using the supercritical fluids. The challenges include high equipment and safety costs, long process times, variable solvent quality during the process, extreme sensitivity due to the diffuse and tunable nature of the fluid, and wafer defectivity/contamination issues arising from the interaction of the supercritical fluid with components of the processing chamber.

Another approach for preventing collapse of the HAR structures during processing is to add a mechanical brace. However, this approach typically has higher cost and process complexity that negatively impact throughput and yield. Furthermore, the mechanical braces are limited to certain types of patterned features.

### SUMMARY

A method includes depositing a film solution onto a patterned feature of a semiconductor substrate after wet cleaning the semiconductor substrate and without performing a drying step after the wet cleaning. The film solution includes a dielectric film precursor or a dielectric film precursor and at least one of a reactant, a solvent, a surfactant and a carrier fluid. The method includes baking at least one of solvent and unreacted solution out of a film formed by the film solution by heating the substrate to a baking temperature.

In other features, the method includes, prior to depositing the film solution and after wet cleaning, rinsing the patterned feature with a rinsing fluid. The rinsing fluid comprises at least one of water, aqueous alcohol and a polar solvent.

In other features, the method includes curing the substrate after baking the film. The curing comprises at least one of heating, thermal annealing, ultraviolet (UV) curing, plasma curing or chemically reactive curing. A curing temperature of the curing is greater than the baking temperature.

In other features, the method includes applying the film solution to the patterned feature using a spin-on approach.

In other features, depositing the film solution includes pre-wetting the semiconductor substrate with a first solution, displacing the first solution using the film solution and spinning the substrate using a spin coater. The displacing and the spinning occur sequentially, simultaneously or overlapping.

In other features, the dielectric film precursor of the film solution includes a polysilazane. The patterned feature includes at least one high aspect ratio (HAR) feature. An aspect ratio of the at least one high aspect ratio (HAR) feature is greater than or equal to 8.

A method includes rinsing a patterned feature of a semiconductor substrate with a rinsing fluid after wet cleaning the semiconductor and without performing a drying step after the wet cleaning. The method includes at least partially displacing the rinsing fluid on the patterned feature using a film solution. The film solution includes a dielectric film precursor or a dielectric film precursor and one of a reactant, a solvent, surfactant and a carrier fluid. The method includes baking at least one of solvent and unreacted solution out of film formed by the film solution by heating the substrate to a baking temperature. The method includes curing the substrate after baking the film.

In other features, the rinsing fluid comprises at least one of water, aqueous alcohol and a polar solvent. The curing comprises at least one of heating, thermal annealing, ultraviolet (UV) curing, plasma curing or chemically reactive curing. A curing temperature of the curing is greater than the baking temperature.

In other features, the method includes applying the film solution to the patterned feature using a spin-on approach. The dielectric film precursor of the film solution includes a polysilazane. The patterned feature includes at least one high aspect ratio (HAR) feature. An aspect ratio of the at least one high aspect ratio (HAR) feature is greater than or equal to 8.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a side cross-sectional view of an example of a substrate including high aspect ratio (HAR) structures;

FIGS. 2A-2D are side cross-sectional views of an example of a substrate including HAR structures during feature fill using spin-on film according to the present disclosure;

FIG. 3 is an example of a method for feature fill of the HAR structures using spin-on film according to the present disclosure;

FIG. 4 is an example of a method for displacing and depositing spin-on film on the HAR structures of the substrate according to the present disclosure; and

FIG. 5A-5C illustrating an example of displacing and depositing spin-on film on the HAR structures of the substrate according to the present disclosure.

In the drawings, reference numbers may be reused to identify similar and/or identical elements.

### DETAILED DESCRIPTION

Systems and methods according to the present disclosure enable collapse-free feature fill of HAR structures using spin-on film deposition after a wafer wet clean step and without a prior drying step. By keeping the surface wet after wet cleaning and transitioning to a liquid precursor for a spin-on film, the method eliminates a vapor/liquid interface between the HAR features that occurs during drying. The capillary forces that are generated during drying are eliminated and the HAR structures can be filled using spin-on film without collapse or stiction.

For example only, the method for film deposition can be performed on a clean track. After wet cleaning, the substrate may be rinsed with a post rinse fluid. In some examples, the post rinse fluid includes water, aqueous alcohol or polar solvent, which remains on the surface with the HAR features. A spin-coater can be used to spin-on a film solution including a film precursor or a film precursor and at least one of a solvent, a reactant, a surfactant or a carrier liquid. If used, the reactant chemical reacts with the film precursor to create a solid film.

For example only, a hot plate or another curing approach can be used to drive out excess or unreacted liquids in the film. In some examples, the deposited film may be a dielectric film. For example only, the solution may be a dielectric solution that includes a dielectric film precursor in an aqueous alcohol solution. The wetted volume on the substrate is displaced by the film solution. The film solution is selected to diffuse through the wetted surface to provide bottom-up fill. In some examples, the film solution operates in a regime that favors gap-fill, such as in shallow trench isolation (STI), pre-metal dielectric (PMD) or inter-metal dielectric (IMD) applications. In an alternative method, only the film precursor is deposited and a diffusion/reaction occurs through the wetted layer.

As can be appreciated, the methods described herein allow deposition of a film such as a dielectric film onto a patterned surface of a substrate such as a semiconductor wafer after wet cleaning and without first drying the surface on which the film is deposited. This approach avoids the problem of having the HAR features collapse or become strained during drying after wet cleaning. This approach also increases process throughput by reducing steps that are required to dry the substrate.

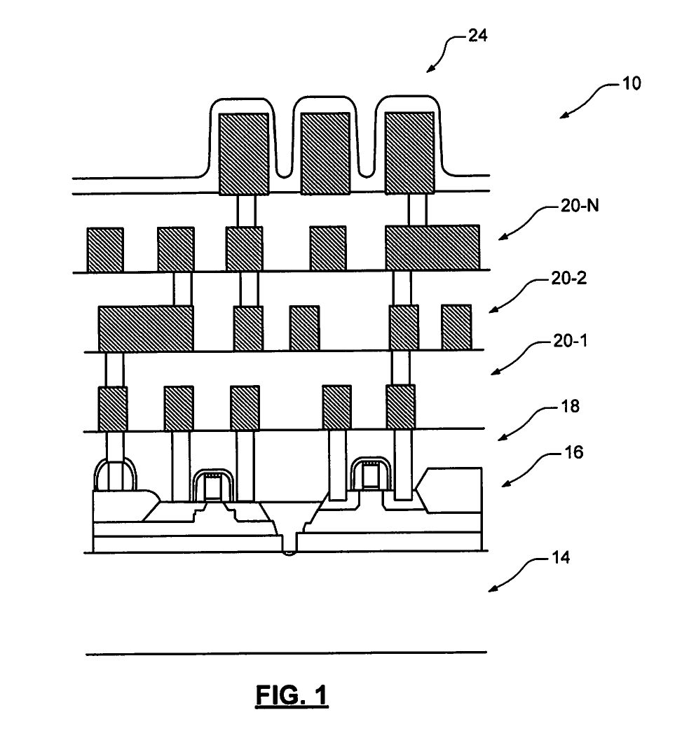

Referring now to FIG. 1, an example of a substrate 10 including high aspect ratio (HAR) structures is shown. The substrate 10 is a semiconductor substrate that includes an underlying substrate layer 14, a semiconductor device 16, a pre-metal dielectric (PMD) layer 18, one or more inter-metal dielectric (IMD) layers 20-1, 20-2, and 20-N (collectively IMD layers 20) where N is an integer greater than zero, and HAR structures 24. In some examples, the HAR structures 24 may include narrow trenches (such as for example 20 nm trenches). In some examples, the HAR structures 24 may have an aspect ratio ≧8, 10, 12, 15, 20 or 50. While a specific example of a substrate is shown, the methods described herein may be used to fill other types of substrates having patterned surfaces with film.

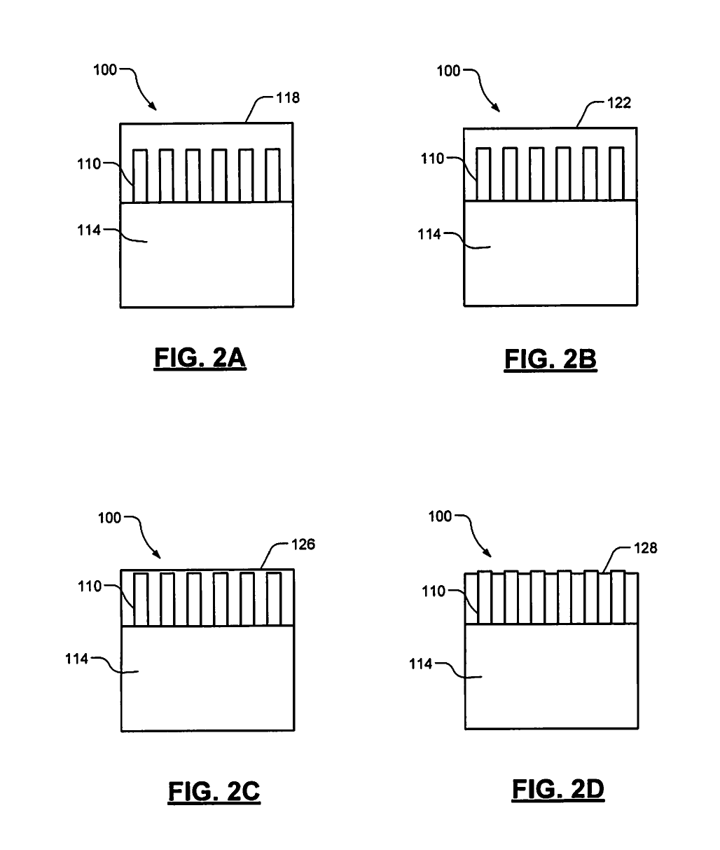

Referring now to FIGS. 2A-2D, an example of a substrate 100 including HAR structures 110 is shown during feature fill of the HAR structures with film after a wafer wet clean step is performed. The feature fill may be performed without a prior drying step. Fluid remains on the HAR structures 110 after a wet clean step. A post rinse fluid 118 may be used to rinse the substrate 100. The post rinse fluid 118 may include water, aqueous alcohol or other polar solvent. In FIG. 2B, a film solution 122 is deposited on the HAR structures 110 and the post rinse fluid 118 is displaced. The film solution 122 may include a film precursor or a film precursor and at least one of a reactant, a solvent, a carrier liquid or a surfactant.

In some examples, the film solution is a dielectric film solution. In some examples, the dielectric film may be a silicon oxide, a silicon nitride, silicon carbide, silicon carbon nitride, aluminum oxide, hafnium oxide, low-k dielectric, or porous dielectric. In some examples, the film solution is a spin-on film solution. In some examples, the film precursor includes one or more polysilazanes, although other film precursors may be used. In some examples, the film solution may include other reactants that will chemically react with the film precursor, such as water, peroxides, or alcohols. In some examples, the film solution may also include catalysts or inhibitors that may, respectively, speed up or slow down the chemical reaction with the film precursor. In some examples, the carrier fluid may include water, aqueous alcohol, solvent, surfactant, or other carrier fluid.

In FIG. 2C, solvent and excess or unreacted liquid in the film created by the film solution is baked out of the film to leave an uncured dielectric layer 128. Thereafter, a curing step or other processing may be performed.

In some examples, the solvent baking of the substrate may occur at a lower temperature than the subsequent curing step. For example only, curing may include heating, thermal annealing, ultraviolet (UV) curing, plasma curing or chemically reactive curing. For example only, the substrate may be cured at high temperature (such as at temperatures ≧300 C-800 C) and/or in the presence of oxygen, ozone, steam or other oxygen-containing gases. For example only, the solvent baking may be performed at a temperature between 75 C and 300 C, such as 150 C.

Referring now to FIG. 3, an example of a method 200 for feature fill of the HAR structures with film after a wet clean step is shown. The feature fill may be performed without a prior drying step. At 202, after wet cleaning of the substrate, a drying step is skipped. At 206, the fluid remaining after the wet clean step is displaced and replaced with a film solution including film precursor or film precursor and at least one of a reactant, a solvent, a carrier fluid and a surfactant. At 210, solvent and excess or unreacted liquid is baked out of the film. At 214, a curing step may be performed.

For example only, hydrolyzed precursor may be used to form Si(OH)₃R′ in solution with H₂O or alcohol. The hydrolyzed precursor is diffused into solution onto the pre-wetted substrate. Polymerization occurs on the wetted substrate to form SiCOH film. For example only, hydrolyzed precursor may be used to form Si(OH)₄ in solution with H₂O. The hydrolyzed precursor is diffused into solution onto the pre-wetted substrate. Polymerization occurs on the wetted substrate to form SiO₂ or SiOxHy film. For example only, an unhydrolyzed precursor may be used which then reacts with H₂O or alcohol in the film solution. Hydrolysis and polymerization occurs on the wetted substrate to form the film. In these examples the film solution reacts to form a sol, gel or solid film on the wetted substrate.

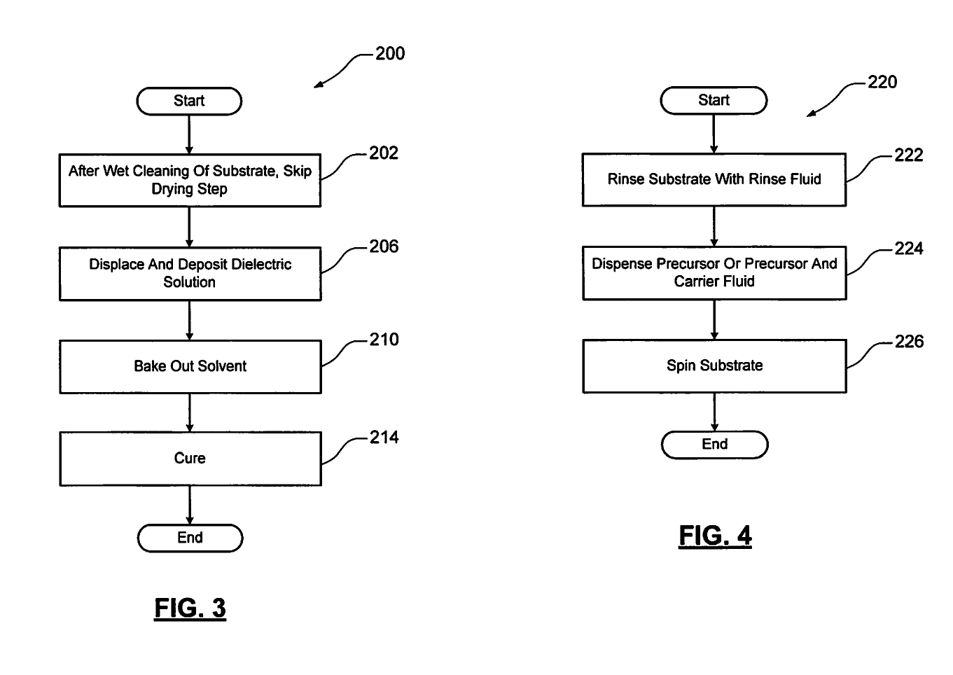

Referring now to FIG. 4, an example of a method 220 for displacing and depositing the film solution is shown. At 222, the substrate is rinsed with a post rinse fluid such as water, an aqueous alcohol solution or a polar solvent. At 224, film precursor or film precursor and at least one of a reactant, a solvent, a carrier liquid and a surfactant is dispensed to displace the post rinse fluid on the substrate. At 226, the substrate is rotated by a spin coater or other device to uniformly distribute the fluid and to remove excess fluid. The displacement and rotation may occur sequentially, at the same time and/or in an overlapping manner.

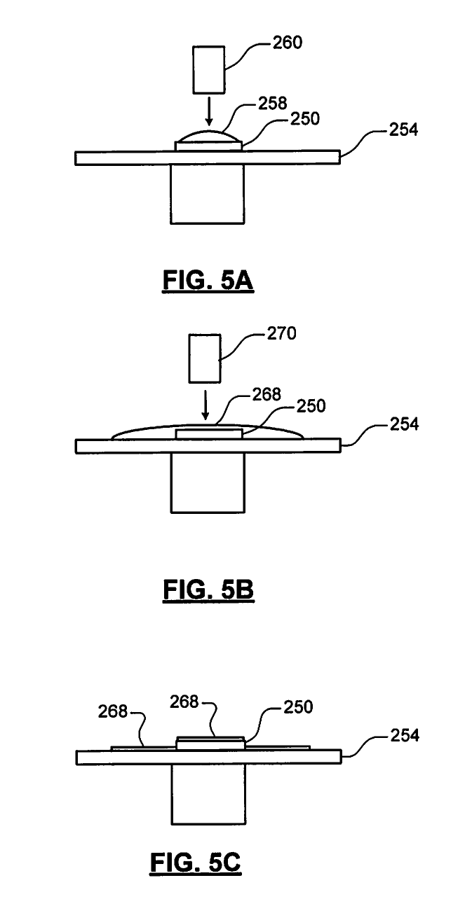

Referring now to FIG. 5A-5C, an example of displacing and depositing dielectric solution is shown. In FIG. 5A, a substrate 250 is arranged on a spin coater 254. A post rinse fluid such as water, aqueous alcohol or polar solvent is deposited onto the substrate 250 from a fluid source 260. In FIG. 5B, a film solution 268 including film precursor or film precursor and at least one of a solvent, a reactant, a carrier fluid or a surfactant is deposited on the substrate 250. As can be appreciated, variations in gap fill may be made by varying a concentration of the film precursor in the film solution, concentration of reactants in the film solution, surface tension of the film solution, hydrophilicity of the film solution, wet time, and spin-off speed.

In FIG. 5C, the spin coater 254 is spun to uniformly distribute the film solution on the substrate 250. The displacement and rotation may occur sequentially, at the same time and/or in an overlapping manner. Some of the solution 268 including the film precursor or the film precursor and carrier fluid remains on the substrate 250. Some of the solution 268 including the film precursor or the film precursor and carrier fluid may be transferred to a surface of the spin coater 254.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. As used herein, the phrase at least one of A, B, and C should be construed to mean a logical (A OR B OR C), using a non-exclusive logical OR, and should not be construed to mean “at least one of A, at least one of B, and at least one of C.” It should be understood that one or more steps within a method may be executed in different order (or concurrently) without altering the principles of the present disclosure.

What is claimed is:

1. A method comprising:
after wet cleaning a semiconductor substrate including a patterned feature:
without performing a drying step after wet cleaning the semiconductor substrate, depositing a film solution onto the patterned feature of the semiconductor substrate,
wherein the film solution includes:
a dielectric film precursor; or
the dielectric film precursor and at least one of a reactant, a solvent, a surfactant and a carrier fluid; and
baking at least one of solvent and unreacted solution out of a film formed by the film solution by heating the substrate to a baking temperature.

2. The method of claim 1, further comprising:
prior to depositing the film solution and after wet cleaning, rinsing the patterned feature with a rinsing fluid.

3. The method of claim 2, wherein the rinsing fluid comprises at least one of water, aqueous alcohol and a polar solvent.

4. The method of claim 1, further comprising curing the substrate after baking the film.

5. The method of claim 4, wherein the curing comprises at least one of heating, thermal annealing, ultraviolet (UV) curing, plasma curing or chemically reactive curing.

6. The method of claim 4, wherein a curing temperature of the curing is greater than the baking temperature.

7. The method of claim 1, further comprising applying the film solution to the patterned feature using a spin-on approach.

8. The method of claim 1, wherein depositing the film solution includes:
pre-wetting the semiconductor substrate with a first solution;
displacing the first solution using the film solution; and
spinning the substrate using a spin coater.

9. The method of claim 8, wherein the displacing and the spinning occur one of sequentially, simultaneously and overlapping.

10. The method of claim 1, wherein the dielectric film precursor of the film solution includes a polysilazane.

11. The method of claim 1, wherein the patterned feature includes at least one high aspect ratio (HAR) feature.

12. The method of claim 11, wherein an aspect ratio of the at least one high aspect ratio (HAR) feature is greater than or equal to 8.

13. A method comprising:
after wet cleaning a semiconductor substrate including a patterned feature:
without performing a drying step after wet cleaning the semiconductor substrate, rinsing the patterned feature of the semiconductor substrate with a rinsing fluid;
at least partially displacing the rinsing fluid on the patterned feature using a film solution,
wherein the film solution includes:
a dielectric film precursor; or
the dielectric film precursor and one of a reactant, a solvent, surfactant and a carrier fluid;
baking at least one of solvent and unreacted solution out of film formed by the film solution by heating the substrate to a baking temperature; and
curing the substrate after baking the film.

14. The method of claim 13, wherein the rinsing fluid comprises at least one of water, aqueous alcohol and a polar solvent.

15. The method of claim 13, wherein a curing temperature of the curing is greater than the baking temperature.

16. The method of claim 13, wherein the curing comprises at least one of heating, thermal annealing, ultraviolet (UV) curing, plasma curing or chemically reactive curing.

17. The method of claim 13, further comprising applying the film solution to the patterned feature using a spin-on approach.

18. The method of claim 13, wherein the dielectric film precursor of the film solution includes a polysilazane.

19. The method of claim 13, wherein the patterned feature includes at least one high aspect ratio (HAR) feature.

20. The method of claim 19, wherein an aspect ratio of the at least one high aspect ratio (HAR) feature is greater than or equal to 8.
